(19) United States
(12) Patent Application Publication
(10) Pub. No.: US 2005/0236266 A1
(43) Pub. Date: Oct. 27, 2005

(54) Sputter target monitoring system

(76) Inventors: John E Poole, Grove City, OH (US); Charles E. Wickersham JR., Arden Road, Columbus, OH (US)

Correspondence Address: WEGMAN, HESSLER & VANDERBURG, 6055 ROCKSIDE WOODS BOULEVARD, SUITE 200, CLEVELAND, OH, 44131, US

(21) Appl. No.: 10/518,293

(22) PCT Filed: Jun. 10, 2003
(86) PCT No.: PCT/US03/19740

§ 371 Date: Dec. 16, 2004

Related U.S. Application Data
(60) Provisional application No. 60/390,057, filed on Jun. 19, 2002.
(60) Provisional application No. 60/398,547, filed on Jul. 25, 2002.
(60) Provisional application No. 60/467,927, filed on May 5, 2003.

(51) Int. Cl. C23C 14/32

(52) U.S. Cl. 204/192.13; 204/298.03

(57) ABSTRACT

A sputtering target monitoring system (20) for monitoring the status of a sputtering source target (22) during the sputtering process. The collection of data is initiated based on measured voltages in the sputtering source target (22), whereas the arcing count is determined based on current spikes or interruptions to the current in the sputtering source target (22) during the sputtering process. The real time data collected during the sputtering process is recorded and displayed in table or graphical format at any time during the sputtering process. Thus, problems in the sputtering process, or in the sputtering source (22), including an approaching end of life of the target may be easily ascertained. Alarms, messages or other indicators may be used to alert operators to problems or conditions during the sputtering process.

### CROSS-REFERENCE TO RELATED APPLICATIONS

The benefit of prior of U.S. Provisional Patent Application Ser. No. 60/390,057 filed Jun. 19, 2002; U.S. Provisional Patent Application Ser. No. 60/398,547 filed Jul. 25, 2002; and U.S. Provisional Patent Application Ser. No. 60/467,927 filed May 5, 2003 is hereby claimed.

### BACKGROUND OF THE INVENTION

1. Field of Invention

This invention relates to a system of monitoring sputter targets based on arc counts identified by current spikes during the sputtering process.

2. Description of Related Art

Conventional sputter target monitoring systems monitor target voltage, current and arcing in real time but do not record or save the data. Other known systems measure arcing but do not sense or account for other parameters, such as voltage, current, impedance, or target life that affect the quality of the deposited films on, or the usefulness of, the sputter targets. In either case, known systems typically require a personal computer on-site to start and control the measurement data regarding the sputter target.

Thus, known sputter target monitoring systems provide no method of remotely recording or saving data reflecting the real time performance of the sputtering target throughout the useful life of the sputter target. Nor, in conventional systems, are alarms provided that are sent by e-mail or pagers with a standard Web browser based on sensed real time data to indicate problems in the sputter target or sputtering tool, or to indicate an approaching end of a target's life.

### SUMMARY OF THE INVENTION

Various exemplary embodiments of the invention separately provide a sputtering target monitoring system comprised of hardware and software to monitor, record and present voltage, current, impedance, arcing and target life factors of a sputter target. In particular, the hardware measures the various factors identified above, whereas the software records and presents the results of the measured factors. The software also provides alarms according to operator selected conditions. The software further enables remote access to the hardware using a standard site network and a standard Web browser.

The sputtering target monitoring system of the invention thus measures and records the various data in real time and compares the data to preset threshold values for the various voltage, current, impedance, arcing, and target life factors. Based on the comparison of the real time acquired data to the preset threshold values, an alarm may be generated to inform an operator of potential problems in either the sputter target or the sputtering tool, or to indicate the approaching end of a target's life.

The sputter target monitoring system of the invention, for example, measures (via the hardware) and records (via the software) the average target voltage and current for each deposition cycle during the entire life of the target. The number of arcing events occurring during sputtering of the target is similarly recorded during each deposition cycle. The arcing events, for example, may be recorded in up to ten second intervals. Recording the arcing events in this manner permits an operator to identify when the arcing happened during the deposition cycle.

The real time and historical data for the target being sputtered is thus retrievable at any time during the process through the software. In this manner, the manufacturer of the target may monitor the sputtering process and the target remotely, and observe in real time the condition of the target and the sputtering tool. Such monitoring enables the manufacturer, for example, to inform customers of target life, and/or target or tool problems at any stage of the sputtering process.

The performance of a sputter target is thus measurable based on voltage, current, impedance, arcing and target life factors. Recording data on these factors over the entire life of a sputter target provides information regarding the sputter target and the sputter tool used to generate films. Unexpected fluctuations in any of these factors may indicate changes, or problems, in either of the sputter target or the sputtering tool. The identification of these fluctuations, if any, by the hardware and software of the invention, enable problems to be forwarded to an operator by alarm, e-mail or other messaging indicator thereby advising the operator to cease sputtering until the source of the fluctuations is addressed if needed.

Various conditions in either the sputter target or the sputter tool may contribute to such unexpected fluctuations in the voltage, current, impedance or arcing factors. For example, backfill pressure in the sputter chamber, varying sputter shield conditions, variable sputter target temperatures, or even small variations in the microstructure of the sputter target may lead to unexpected fluctuations in any of the voltage, current, impedance, arcing or target life factors. All of these factors and conditions thus affect the quality of the film deposited.

For example, the generation of arcing from the sputtering target or the sputter chamber shielding often results in particles being undesirably deposited in the film. Such particles cause defects in the deposited films. Any defects in the sputter targets lowers the yield of substrates produced by the sputter targets.

The life of a sputter target is also a concern as the sputtering tool tends to be damaged if the target is sputtered beyond its capacities. In other words, the metals or other materials of the sputter target may be removed so much, due to lengthy sputtering time or intense sputtering power, such that the target is actually sputtered through. Such sputtering through of the target thus leaves the sputtering tool subject to damage. Predicting the target life of a sputter target therefore is a useful indicator to minimize the likelihood of damage to the sputtering tool.

The target life, measured in kilowatt hours (kWHrs), of a target is based on the sputtering target power (kW) and the time (Hrs) the target is sputtered. By tracking the target life (kWHrs) of a sputter target during sputtering, an alarm can be used to indicate the end of the target life of the target is near. In this manner, sputtering can be stopped before the target's capacity is exhausted and the target sputtered through. Thus, preventing the sputtering through targets minimizes damage to the sputtering tool that otherwise often takes place when sputtering through the target occurs.

These and other features and advantages of this invention are described in, or are apparent from, the following detailed description of various exemplary embodiments of the systems and methods according to this invention.

### BRIEF DESCRIPTION OF THE DRAWINGS

Various exemplary embodiments of the systems and methods of this invention will be described in detail with reference to the following figures wherein:

FIG. 1 illustrates a conventional sputtering system;

FIG. 2 illustrates an exemplary embodiment of the hardware and software systems according to the invention;

FIG. 3 illustrates a voltage circuit according to the invention;

FIG. 4 illustrates a current circuit according to the invention; and

FIG. 5 illustrates an arc sensing circuit according to the invention.

### DETAILED DESCRIPTION OF EXEMPLARY EMBODIMENTS

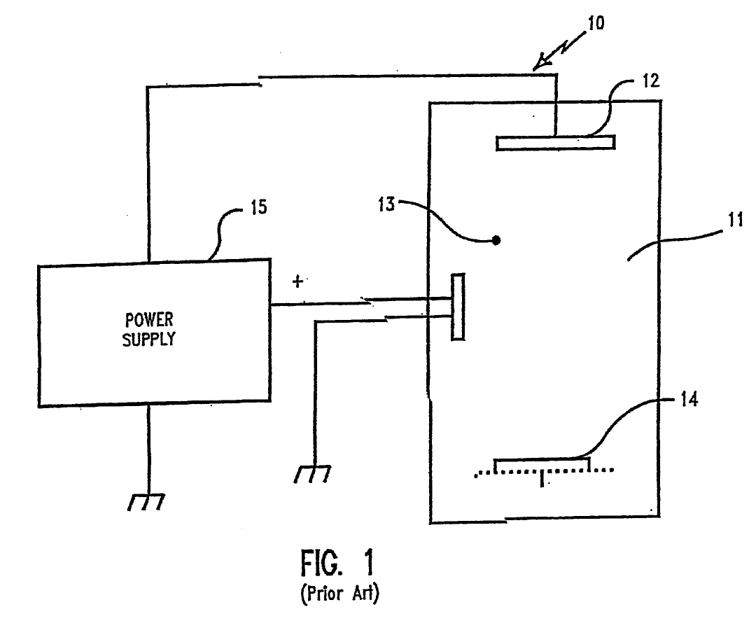

FIG. 1 shows a conventional physical vapor deposition sputtering system used for forming thin film metal layers on wafers used for integrated circuits (IC) for example. The system comprises a vacuum chamber 11, target 12 formed of a metal or insulator, anode 13, substrate 14 and power supply 15. The sputtering technique involves placing the target 12 in the vacuum chamber 11. The target 12 is electrically connected as a cathode. The anode 13 provides a ground. The power supply 15 generates an electric field between the target 12 and anode 13 such that a low pressure gas, such as argon, ionizes in the vacuum chamber 11. The ionized gas atoms accelerate across the electric potential and impact the target 12 at high speeds, causing metal atoms from the target to be removed, or sputtered, from the target 12. The metal atoms ejected from the target material travel virtually through the low pressure gas relatively easily and attach to the substrate 14 to form an approximately uniform coating on the substrate 14.

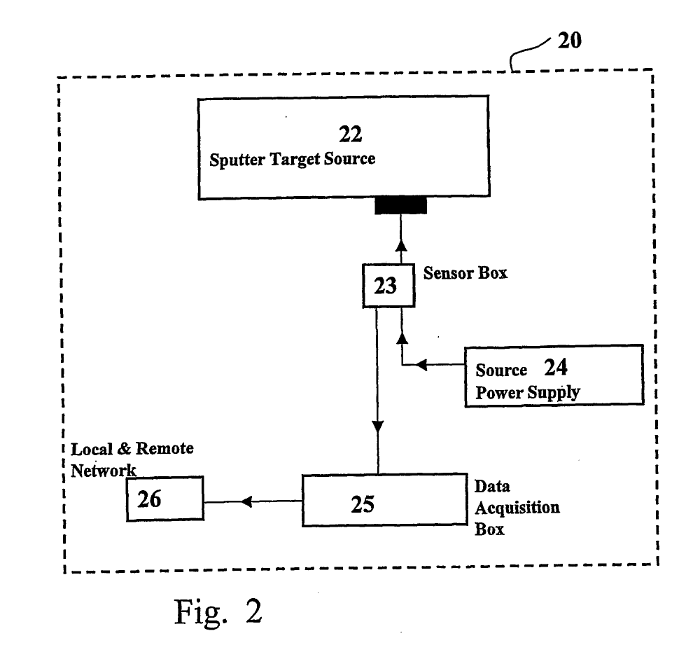

FIG. 2 shows a diagrammatic view of the sputter target monitoring system 20 according to the invention. The system 20 generally comprises a sputter source target 22, a power supply 24 and a network 26. A sensor box 23 connects the power supply 24 to the sputter source target 22. A data acquisition box 25 connects the sensor box 23 and the network 26.

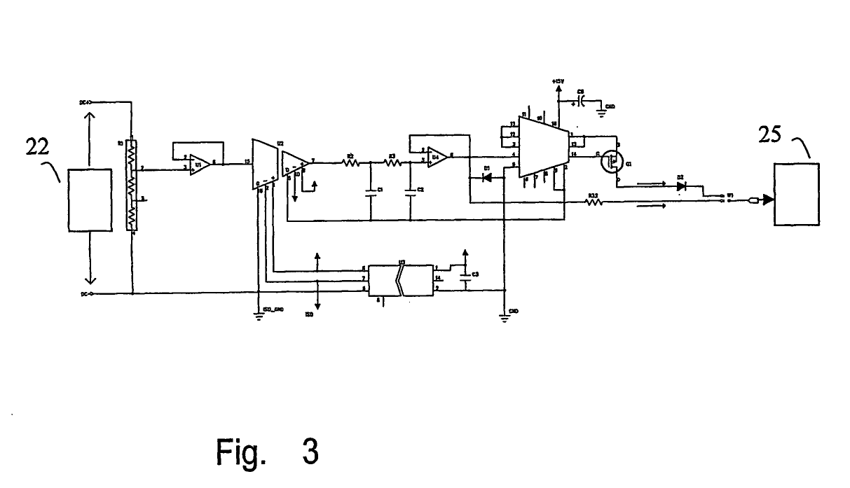

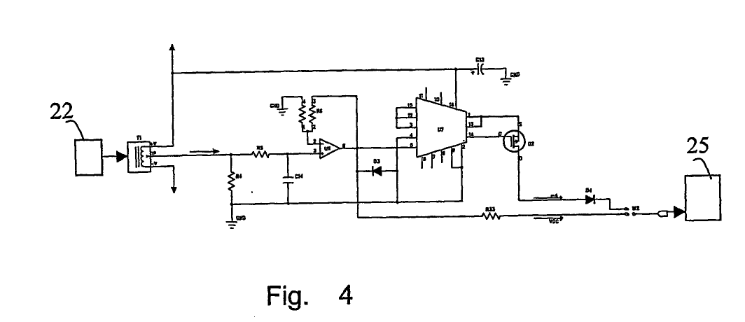

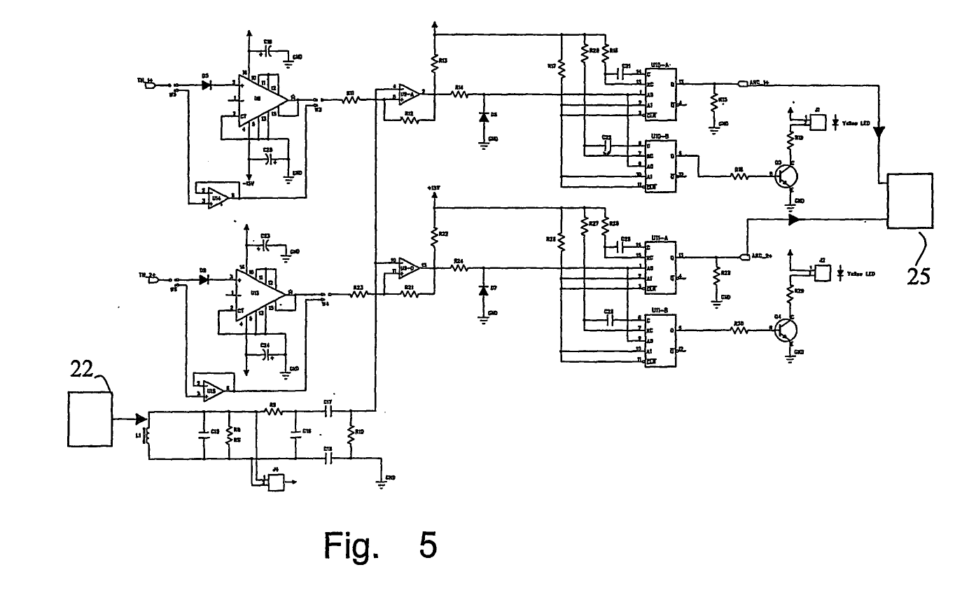

The sensor box 23 comprises the hardware of the system 20. The hardware is comprised of three independent circuits that measure the voltage, current and arcing respectively, occurring in the sputtering source target 22 during the sputtering process. The voltage circuit is shown in FIG. 3, the current circuit is shown in FIG. 4, and the arc sensing circuit is shown in FIG. 5.

The voltage circuit (FIG. 3) measures a voltage signal from a cathode of the sputtering source target 22 and provides that signal to the data acquisition box 25. If the voltage measured by the voltage circuit exceeds a threshold voltage value, then sputtering is occurring and data regarding the sputtering source target 22 is collected. If the voltage measured by the voltage circuit is less than the threshold voltage value, then sputtering is not occurring and no data is collected. The data acquisition box 25 thus uses the voltage signal from the voltage circuit to determine On/Off status of the deposition cycle, and to calculate target life and impedance, for example, of the sputter target.

As shown in FIG. 3, if the voltage measured by the voltage circuit exceeds the preset threshold value, then the voltage signal propagates through the voltage circuit (FIG. 3) with sufficient magnitude to activate the transistor gate thereby generating and propagating an enhanced signal to the data acquisition box 25. In this case, sputtering is occurring, and data regarding the sputtering source target 22 is collected. In contradistinction, if the voltage measured by the voltage circuit (FIG. 3) is less than the preset threshold value, then the voltage signal is not of sufficient magnitude to activate the transistor gate, no enhanced signal is generated, and no signal propagates to the data acquisition box 25. In this case, sputtering is not occurring and no data regarding the sputtering source target 22 is collected.

The current circuit (FIG. 4) similarly measures a current signal from the cathode of the sputtering source target 22 and provides that signal to the data acquisition box 25. This data is similarly used to calculate target life and impedance of a sputter target.

As shown in FIG. 4, if the current measured by the current circuit exceeds the preset threshold value, then the current signal propagates through the current circuit (FIG. 4) with sufficient magnitude to activate the transistor gate thereby generating and propagating an enhanced signal to the data acquisition box 25. In this case, sputtering is occurring and data regarding the sputtering source target 22 is collected. In contradistinction, if the current signal measured by the current circuit (FIG. 4) is less than the preset threshold value, then the current signal is not of sufficient magnitude to activate the transistor gate, and no enhanced signal is generated, and no signal propagates to the data acquisition box 25. In this case, sputtering is not occurring, and no data regarding the sputtering source target 22 is collected.

The arc sensing circuit (FIG. 5) measures spikes or other interruptions in the current of the sputter target and compares the signal of those spikes or other interruptions to preset threshold values in a comparator circuit of the arc sensing circuit. If the measured current spike or interruption is greater than the threshold value then an arcing event is deemed to have occurred and the arcing event is counted by a counting circuit in the arc sensing circuit. The current spiking or interruptions are recorded in every deposition cycle in one to ten second intervals. The number of arcing events is then provided to the data acquisition box 25. The comparator circuit of the arc sensing circuit thus determines and counts arcing events based solely on spikes or other interruptions in the current of the sputter source target 22.

As shown in FIG. 5, if the measured current spike or interruption exceeds the preset threshold values, then the output signals generated by the comparator OPAMP devices serve to reverse bias the grounded rectifier diodes thereby propagating the enhanced signal through the digital counter IC chips in the arc sensing circuit (FIG. 5). In this case, an arcing event is deemed to have occurred and the arcing event is counted by the digital counting circuit in the arc sensing circuit. In contradistinction, if the current measured by the current circuit does not exceed the preset threshold values, then the output signals generated by the comparator OPAMP devices serve to forward bias the grounded rectifier diodes thereby creating a short-circuit grounding the output signal. In this case, no arcing event is deemed to have occurred and no arcing event is counted by the digital counting circuit in the arc sensing circuit.

The data acquisition box 25 processes and stores all of the data provided to it from the various circuits in the sensor box 23. The data acquisition box 25 is comprised of an analog input module, a counter module, an Ethernet controller module, and power supplies. The Ethernet controller module thus controls the data acquisition box 25 and effectively runs the sputtering target monitoring system therefore. A local graphic touch screen display may be provided to manipulate, monitor and control the sputtering target monitoring process.

A series of screens may be used to provide information specific to each sputtering process. For example, a Main Screen may view sputtering process parameters based on the composition of the sputter target source, the sputter target power, the length of time of each cycle, the number of cycles to be performed, the steady state voltage and current conditions, the type of alarm or indicator/messaging desired, the target life, the substrate being coated, and other factors pertinent to the sputtering process. The company the substrate is being prepared for may also be included in one of the screens when undertaking a sputtering process. In this manner, the manufacturer may advise the company of the sputtering process as it occurs.

A Settings Screen permits user inputs with respect to various voltage, current and arcing thresholds, alarm/indicator preferences, power supply set-up, and clock/date set-up, for example.

A Summary Screen produces data measured during a sputtering process to be displayed in spreadsheet format, for example. The Summary Screen may include the parameters set forth in the Main Screen and the Setting Screen, for example.

A Graphics Screen permits the data provided in the Summary Screen to be displayed in graphical form. For example, the sputtering process may be exhibited in a Voltage/Current per cycle format, or in an Arcing per cycle format.

A Demo Screen, when provided, permits a user to run a demonstration of monitoring a hypothetical sputtering process without being attached to a sputtering source target.

In operation, the sensor box 3 connects the power supply 24 to the cathode side of the sputter source target 22. The sensor box 23 also connects to the data acquisition box 25. The data acquisition box 25 is connected to the network 26, which may be a local personal computer or may be a remote system. In either case, the operator inputs the customer and sputter target information into the computer or remote system by inputting the information to the Main Screen, for example. Next, the operator inputs the sputter source target parameters into the Settings Screen. The sputter monitoring system is thus ready to run when power to the sputtering tool is provided.

Once the sensor box 23 senses a voltage value in the sputter source target 22 that is greater than the designated threshold voltage value, the data collection box 25 begins to collect data on the sputter target source 22. The voltage and current of the sputter source target 22 is thus measured every one second, for example. The condition of the sputter source target 22 during each deposition cycle is then compared to set thresholds to determine if any oddities are occurring. If oddities, such as high voltage are occurring, then an alarm, indicator or other message, is communicated to the operator to cease the sputtering operation until that which is causing the oddity to occur is corrected. If no oddities are determined, then sputtering and monitoring thereof continues.

The arc sensing circuit provided in the sensor box 23 also senses any spikes, or interruptions, in current values in the sputtering source target 22 during the sputtering process. If current spikes beyond a threshold current value, or if interruptions in the current of the sputtering source target 22 occurs, then the spikes or interruptions are counted as arcing events. Each deposition cycle is measured for arcing events in one to ten second intervals. The arcing events are thus recorded by the data collection box 25, which permits the operator to graphically display the arcing events occurring in any deposition cycle. The operator can set two different arcing threshold values, i.e., based on different current values, such that spikes or interruptions to the different arcing threshold values can be simultaneously recorded and displayed in real time.

While this invention has been described in conjunction with the specific exemplary embodiments above, it is evident that many alternatives, combinations, modifications, and variations are apparent to those skilled in the art. Accordingly, the preferred embodiments of this invention, as set forth above are intended to be illustrative, and not limiting. Various changes can be made without departing from the spirit and scope of this invention.

1. A sputtering target monitoring system comprising:
a sputtering source in a vacuum chamber;
a power supply;
a sensor box connected to the sputtering source and the power supply, the sensor box including a current-based arcing sensing device;
a data collection box connected to the sensor box; and
a network connected to the data collection box.

2. The sputtering target monitoring system recited in claim 1, wherein the sensor box further comprises a voltage circuit, a current circuit and the current-based arcing sensing device.

3. The sputtering target monitoring system recited in claim 2, wherein the data collection box further comprises software for collecting and displaying data collected from the sputtering source.

4. The sputtering target monitoring system recited in claim 3, wherein the data collection occurs according to a voltage sensed in the voltage circuit exceeding a threshold voltage value in the sputtering source.

5. The sputtering target monitoring system recited in claim 4, wherein arcing events correspond to current spikes sensed in the sputtering source beyond a threshold current value.

6. The sputtering target monitoring system recited in claim 4, wherein arcing events correspond to current interruptions sensed in the sputtering source.

7. The sputtering target monitoring system recited in claim 1, wherein the network is directly linked to the sputter monitoring system.

8. The sputtering target monitoring system recited in claim 1, wherein the network is remotely linked to the monitoring system.

9. The sputtering target monitoring system recited in claim 1, wherein the data collection box provides real time display of data collected.

10. The sputtering target monitoring system recited in claim 9, wherein the real time display is at least one of a table format and a graphical format.

11. A method of monitoring a sputtering process comprising:
providing a monitoring system comprising a sputtering source in a vacuum chamber, the sputtering source being connected to a power supply and a sensor box in the vacuum chamber, and the sensor box including a current-based arcing sensing device;
providing a real time data collection box connected to the sensor box, and a network connected to the data collection box, the data collection box recording and displaying collected data pertaining to the sputtering source;
inputting threshold values to the monitoring system;
starting the sputtering process;
measuring voltage values in the sputtering source during each cycle of the sputtering process to determine when initiation of data collection occurs during each cycle;
measuring current values in the sputtering source during the sputtering process and comparing the measured current values to corresponding threshold values to determine when arcing occurs in each cycle; and
indicating the status of the sputtering process based on the real time data collected.

12. The method recited in claim 11, further comprising displaying the measured results to monitor the conditions during the sputtering process in at least one of a table format and a graphical format.

13. The method of claim 11, further comprising determining the life of the target based on a number of kW hours the sputtering source has undergone.

14. The method of claim 11, wherein indicating the status of the sputtering process comprises notifying an operator of conditions during the sputtering process by at least one of alarms, messaging, lighting, and paging.

15. The method of claim 14, wherein the monitoring system is operable by a direct on-site computer or remotely by a network link.
